(19) United States
(12) Patent Application Publication
(10) Pub. No.: US 2025/0329755 A1
(43) Pub. Date: Oct. 23, 2025

(54) CELL VOLTAGE PICKUP HAVING A GRID GEOMETRY

(71) Applicant: MARQUARDT GMBH, Rietheim-Weilheim (DE)

(72) Inventors: Elmar NEUGART, Villingen-Schwenningen (DE); Peter BROGHAMMER, Wurmlingen (DE)

(21) Appl. No.: 18/861,647

(22) PCT Filed: Aug. 24, 2023
(86) PCT No.: PCT/EP2023/073241

§ 371 Date: Oct. 30, 2024

(30) Foreign Application Priority Data
Nov. 10, 2022 (DE) 10 2022 129 736.5

(51) Int. Cl. H01M 8/0202

(52) U.S. Cl. CPC H01M 8/0269

(57) ABSTRACT

A fuel cell voltage pickup (100) for electrically contacting a contact device of a fuel cell stack (20) of the fuel cell has electrical contact sockets (21) arranged in one or more rows and/or columns. The contact device has a housing (15). The cell voltage pickup (100) has spring contact elements (11) at corresponding positions. The spring contact elements are formed by a wire loop and extend away from the cell voltage pickup (100) in the plug-in direction (S). The spring contact elements (11) form a needle-ear-shaped wire loop (12) that is resiliently compressed when the spring contact 10 elements are inserted into the contact sockets (21). Thus, two wire loop sections (12a, 12b) of the wire loop (12) of the spring contact elements (11) are pressed transversely to the plug-in direction (S), against the contact sockets (21), under a spring force. The contact sockets (21) have a latching (23) that secure the wire loops (12) in the plugged-in state.

The disclosure relates to a cell voltage pickup, CVP.

A cell voltage pickup, CVP, is a multi-channel potential tap for detecting cell voltages across battery or fuel cell stacks as well as bipolar plates. Depending on the stack used, different design principles are employed.

Such an apparatus is known in the prior art, for example from JP 002002313398 A. This pickup is for measuring a cell voltage capable of simultaneously and easily measuring the voltages of all cells of a fuel cell stack. It comprises a plurality of probes for voltage measurement and needle-shaped voltage measuring terminals having a tip side projecting from the pickup, and a spring supported within the pickup that biases the needle-shaped voltage measurement terminals against the side faces of the separators of the fuel cell stack by an elastic force.

A disadvantage of this solution is the complex structure, as well as the issue that the contacts or contact sockets may be damaged upon insertion and that a high insertion force, specifically in case of a large number of fuel cell connections, is required.

Therefore, the object of the disclosure is to overcome the aforementioned disadvantages and provide a solution for a fuel cell stack to contact a plurality of bipolar plates placed parallel to and on top of one another in a secure, quick and reliable and, in particular, automated manner for tapping and subsequently forwarding a cell voltage to measuring and evaluation electronics. Furthermore, it must be ensured that each individual contact is also received into the respective contact opening in the bipolar plate without being damaged and a good contact force is achieved.

It is a further object to provide reliable and secure contacting that will not accidentally disengage during operation.

This object is achieved by the combination of features according to claim 1.

The basic principle of the disclosure is that a specifically shaped resilient contact part having a “loop” shape will laterally compress in the loop section upon being inserted into the corresponding contact pocket. The width of the wire loop in the loop section becomes larger than the opening width on the counter contact side so as to achieve secure contacting. Due to the loop design, deflection on both sides is achieved. Optionally, the wire loop, prior to reaching its final position, may additionally be resiliently deflected transversely to the plug-in direction by an assembly. This allows for the connection to be established using a generally low, but defined, insertion force, and once fully plugged in, a high contact force may be generated.

Optionally, to improve fixation, pre-centering may be achieved via the housing providing a guiding leg or guiding ribs.

Therefore, a cell voltage pickup according to the disclosure is provided for electrically contacting a contact device of a fuel cell stack having electrical contact sockets arranged in one or more rows and/or columns. The contact device has a housing. The cell voltage pickup has spring contact elements at corresponding positions that extend away from the cell voltage pickup in the plug-in direction (S). The spring contact elements form a needle-ear-shaped wire loop at their plug-in end that is resiliently compressed when the spring contact elements are inserted into the contact sockets. Thus, two wire loop sections of the wire loop of the spring contact elements are pressed transversely to the plug-in direction (S) against the contact sockets under a spring force. The contact sockets is provided with a (preferably integral) latch that secures the respective wire loops in the plugged-in state.

In an advantageous embodiment of the disclosure, the contact sockets include a cavity corresponding to the shape of the wire loops or a correspondingly shaped receiving space where the respective wire loop, when being in the plugged-in state, electrically contacts the contact socket partially or along the entire wire loop sections (while basically forming a loop having a central opening).

Another advantage is that, when being in the plugged-in state, a latching tip, detent or protrusion (as a latching means) provided in the region of the respective cavity protrudes at least partially or entirely through the opening in the wire loop. In such an embodiment, the loop may surround the tip resulting in the tip securely engaging the opening of the loop.

Yet another advantage is a design where a sloping ramp is provided in the region of the cavity, forward of the latch when viewed in the plug-in direction, serving as a sloping slide bearing plane for guiding the wire loop into the plug-in position upon insertion.

In an advantageous embodiment of the disclosure, the cavity to comprises rounded side walls as a lateral counter bearing for resiliently installing the wire loop sections of the wire loop. It is particularly advantageous for the cavity and/or the latching tip/detent to be manufactured by thermoforming.

In another advantageous embodiment of the disclosure, the main component of the spring force pressing the wire loop of the spring contact elements against a side wall of the contact sockets when being in the plugged-in state is provided to act transversely to the plug-in direction.

With the cell voltage pickup formed, upon insertion of the spring contact elements of the cell voltage pickup into the contact sockets of the fuel cell stack, it is further advantageous for the wire loop of the spring contact elements to be increasingly compressed during insertion due to the shape of the wire loop. This allows for the insertion force to be specifically controlled through the insertion distance.

In another advantageous embodiment of the disclosure, the respective wire loop is provided to have a shape of a closed wire loop comprised of at least two curved wire loop sections extending adjacent to one another and a bend section connecting the two wire loop sections and formed at their plug-in end.

Another advantage is a design where the spring contact elements, upon insertion, first enter the contact openings of the contact sockets, preferably at about the center, at least with their front end before, while continuing insertion, the two wire loop sections will abut wall sections of the contact sockets. Alternatively, another force component transverse to the plug-in direction may be generated by using two parallel wire loops offset from one another.

Yet another advantage is a design where the contact sockets have a contact cavity comprising, when viewed in the plug-in direction, first a region having a smaller cross-section and a following region having a larger cross-section that receives the wire loop in a clamping manner when fully plugged in.

Therefore, a possible variant may be to form U-shaped contacts each forming two spring contact elements extending substantially parallel to one another (arranged in pairs), each spring contact element being provided to be inserted into a corresponding socket on the contact device of the fuel cell stack.

As another embodiment, the spring contact elements may be provided to have a latching geometry at or near their plug-in end engaging a counter latching geometry formed in or at the contact sockets. This causes the contact assembly to be securely retained.

Another aspect of the present disclosure relates to such a contact assembly comprised of a fuel cell stack having socket contacts and a cell voltage pickup as described above configured to be inserted into electrical contact with the fuel cell stack.

Yet another aspect of the present disclosure relates to a fuel cell comprising a fuel cell stack having a plug-in device configured with socket contacts and a cell voltage pickup as described above that is inserted or insertable into electrical contact with the fuel cell stack.

The features disclosed above can be combined as required, provided this is technically possible and they do not contradict one another.

Other advantageous refinements of the disclosure are characterized in the subclaims and/or depicted in greater detail below together with the description of the preferred embodiment of the disclosure with reference to the figures.

In the drawings:

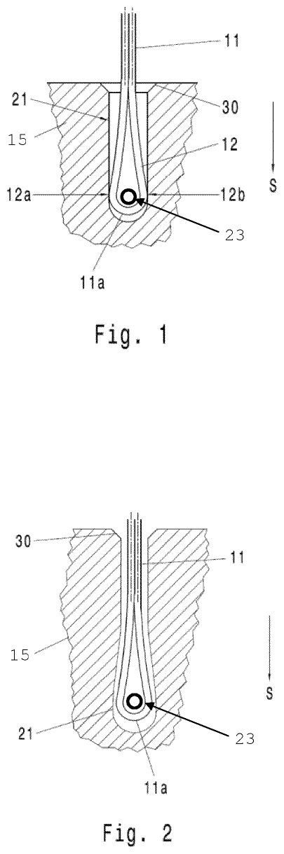

FIG. 1 is a schematic sectional view of a detail of a first embodiment of a cell voltage pickup.

FIG. 2 is a schematic sectional view of a detail of an alternative embodiment of a cell voltage pickup, in a plug-in position,

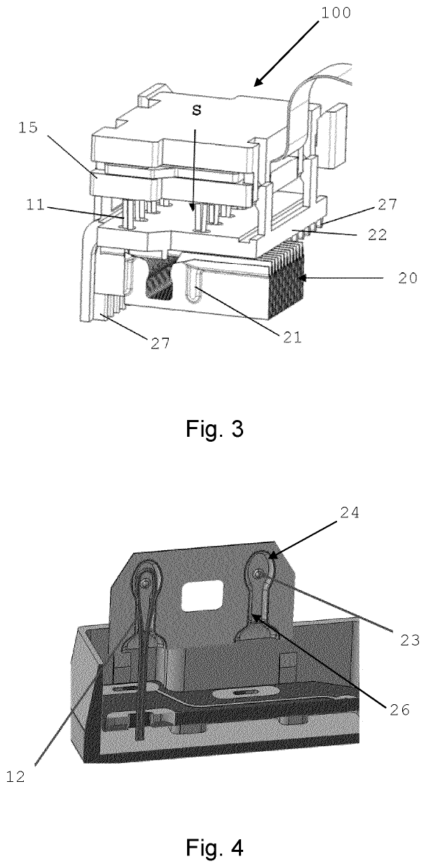

FIG. 3 is a perspective sectional view of a cell voltage pickup showing a plurality of contacts.

FIG. 4 is a detailed view of the cavities receiving the loop contacts, and

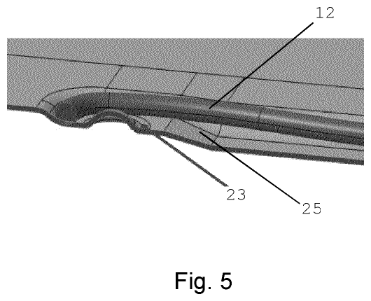

FIG. 5 is another detailed view of a section of FIG. 4.

FIGS. 1 to 5 are schematic examples. Same reference symbols in the figures indicate same functional and/or structural features.

FIG. 3 shows a perspective view of a cell voltage pickup 100. The cell voltage pickup 100 is configured for electrically contacting electrical contact sockets 21 arranged in multiple rows and/or columns in a housing 1 of a fuel cell stack 20, the cell voltage pickup 100 having the spring contact elements 11 shown at corresponding positions. The spring contact elements 11 extend in the plug-in direction S away from the cell voltage pickup 100 (downward in FIG. 3), wherein guiding ribs 27 are arranged on the housing 15 of the counter plug-in device of the fuel cell stack 20, when viewed in the plug-in direction S, to ensure pre-centering prior to the actual insertion operation. Reference symbol 22 shows a guiding region for pre-centering the spring contact elements 11.

FIG. 1 shows a schematic exemplary embodiment of the of a partial section of a schematic sectional view of a cell voltage pickup 100 being connected with a contact device of a fuel cell stack 20, in a mounting position in the fully plugged-in state at the end of the insertion operation.

The loop-like spring contact elements 11 formed from wire, upon insertion, are first inserted at least with their front end 11a (front bend section 11a of the wire loop 12) into the contact openings of the contact sockets 21 at about the center of the respective contact opening. Subsequently, while continuing insertion, the respective lower loop section of the two wire loop sections 12a, 12b of the spring contact elements 11 will abut the edge of the opening regions of the contact cavities of the contact sockets 21.

The alternative exemplary embodiment of FIG. 2 shows a solution different from the first exemplary embodiment, where the contact cavity of the contact socket 21 shows a lower widened contact receiving region where the wire loop may resiliently decompress to some degree by causing the two wire loop sections (loop sections 12a, 12b, respectively) to spring back transversely to the plug-in direction S towards the walls of the contact sockets 21.

FIGS. 4 and 5 explain the latching principle in greater detail. The contact cavities 24 of the contact sockets 21 are shown each having a latch 23, configured as a latching tip, formed therein. The contact cavities 24 are delimited by rounded side walls 26. The ramp 25 can be seen in FIG. 5. It is located in the region of the cavity 24 forward of the latch 23 when viewed in the plug-in direction and serves as a sloping slide bearing plane for the wire loop 12 upon insertion into the plug-in position.

The side walls 26 serve as a lateral counter bearing for resiliently installing the wire loop sections 12a, 12b of the wire loop 12. As can be seen in FIGS. 4 and 5, the wire loop 12 surrounds the tip-like latch 23 and is secured thereto to prevent it from being pulled out, and/or the separating force is increased according to the geometry of the latching elements involved.

The disclosure is not limited in its execution to the abovementioned preferred exemplary embodiments. Rather, a number of variants are conceivable that make use of the illustrated solution even in the form of fundamentally different embodiments.

1-12. (canceled)

13. A fuel cell voltage pickup for electrically contacting a contact device of a fuel cell stack of the fuel cell having electrical contact sockets arranged in one or more rows and/or columns, the contact device comprising:
a housing, the cell voltage pickup having spring contact elements at corresponding positions, the spring contact elements being formed by a wire loop and extending away from the cell voltage pickup in the plug-in direction, the spring contact elements forming a preferably needle-ear-shaped wire loop that is resiliently compressed when the spring contact elements are inserted into the contact sockets such that two wire loop sections of the wire loop of the spring contact elements are pressed transversely to the plug-in direction against the contact sockets under a spring force, and the contact sockets being provided with a latch that retains in position or secures the wire loops in the plugged-in state.

14. The cell voltage pickup according to claim 13, wherein the contact sockets have a cavity or receiving space corresponding to the shape of the wire loops where the respective wire loop, when being in the plugged-in state, electrically contacts the contact socket along the entire wire loop sections.

15. The cell voltage pickup according to claim 13, wherein, when being in the plugged-in state, a latching tip, detent or protrusion provided in the region of the respective cavity protrudes at least partially or entirely through the opening in the wire loop.

16. The cell voltage pickup according to claim 14, wherein the region of the cavity, forward of the latch when viewed in the plug-in direction, a sloping ramp is provided that serves as a sloping slide bearing plane for the wire loop upon insertion into the plug-in position.

17. The cell voltage pickup according to claim 14, wherein the cavity comprises rounded side walls as a lateral counter bearing for resiliently installing the wire loop sections of the wire loop.

18. The cell voltage pickup according to claim 14, wherein the cavity and/or the latching tip/detent are/is manufactured by thermoforming.

19. The cell voltage pickup according to claim 13, wherein the main component of the spring force pressing the wire loop of the spring contact elements against a side wall of the contact sockets when being in the plugged-in state acts transversely to the plug-in direction.

20. The cell voltage pickup according to claim 13, wherein, upon insertion of the spring contact elements of the cell voltage pickup into the contact sockets of the fuel cell stack, the wire loop of the spring contact elements is increasingly compressed during insertion due to the shape of the wire loop.

21. The cell voltage pickup according to claim 13, wherein the respective wire loop made of wire has a shape of a closed, resiliently deformable wire loop comprised of at least two curved wire loop sections extending adjacent to one another and a bend section connecting them and formed at their plug-in end.

22. The cell voltage pickup according to claim 13, wherein the spring contact elements, upon insertion, first enter the contact openings of the contact sockets at least with their front end, followed by being guided across a slide bearing plane of a sloping ramp, and then the wire loop is moved over the latch.

23. A contact assembly comprised of a fuel cell stack having socket contacts and a cell voltage pickup according to claim 13 configured to be inserted into electrical contact with the fuel cell stack.

24. A fuel cell comprising a fuel cell stack configured with socket contacts and a cell voltage pickup according claim 13 that is inserted or insertable into electrical contact with the fuel cell stack.
